(19) United States
(12) Patent Application Publication
(10) Pub. No.: US 2025/0219349 A1
(43) Pub. Date: Jul. 3, 2025

(54) HYBRID SILICON QUANTUM DOT LASERS (HSQDL) WITH REDUCED THERMAL RESISTANCE

(71) Applicant: Intel Corporation, Santa Clara, CA (US)

(72) Inventors: Duanni Huang, San Jose, CA (US); Guan-Lin Su, Sunnyvale, CA (US); Karan Mehta, San Francisco, CA (US); Shane Yerkes, Placitas, NM (US); Razi Dehghannasiri, Albuquerque, NM (US); Stanley Dobek, Rio Ranch, NM (US); Marcus Cramer, Rio Ranch, NM (US); Harel Frish, Albuquerque, NM (US); Haisheng Rong, Pleasanton, CA (US)

(73) Assignee: Intel Corporation, Santa Clara, CA (US)

(21) Appl. No.: 18/399,484

(22) Filed: Dec. 28, 2023

(51) Int. Cl. H01S 5/02; G02B 6/12; G02B 6/122; H01S 5/026; H01S 5/227

(52) U.S. Cl. CPC H01S 5/021; G02B 6/122; H01S 5/026; H01S 5/2275; G02B 2006/12061; G02B 2006/12121

(57) ABSTRACT

Hybrid silicon quantum dot laser (HSQDL) structure including an optical waveguide of a first width, a mesa of a second width and a current channel of a third width that is smaller than the second width. In some examples, the third width is only slightly larger than the first width to narrowly confine electrical current directly over the optical waveguide while the third width is significantly larger than the first width to efficiently transport heat away from the optical gain medium. While the current channel has a low electrical resistivity, other regions of the mesa contributing to the third width have a higher electrical resistivity. In some examples, an implant process is practiced to increase electrical resistivity.

### BACKGROUND

Photonic Integrated Circuits (PICs) are increasingly important in high-performance computing, data center, and cloud computing applications. The use of silicon in photonics (SiPh), enables high-volume, low-cost and highly integrated PICs. The provisioning of on-chip laser sources is a critical path in PIC development, particularly for applications relying on dense wavelength division multiplexing (DWDM). Along with lower manufacturing costs, the integration of laser source(s) directly on silicon would reduce coupling losses for SiPh applications.

A promising laser source architecture known as a “hybrid silicon quantum dot laser” (HSQDL) integrates III-V QD material with a silicon substrate comprising an optical waveguide and potentially other passive optical components such as (de) multiplexers, grating couplers, and/or active components such as modulators, semiconductor optical amplifiers (SOAs) and photodetectors. For HSQDL architectures, quantum dot gain material promises better performance than has been achieved by silicon hybrid lasers relying on quantum well (QW) gain (active) material. For example, HSQDL architectures have displayed higher operating temperatures and a greater tolerance to optical feedback.

Accordingly, new HSQDL architectures offering further improved performance and/or addressing some limitations of prior architectures would be commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram of methods for fabricating a HSQDL, in accordance with some embodiments;

FIG. 2A is a plan view of a silicon PIC substrate, in accordance with some embodiments;

FIG. 2B is a cross-sectional profile view of a silicon PIC substrate, in accordance with some embodiments;

FIG. 3 is a cross-sectional profile view of a P-i-N diode structure comprising one or more layers of QD material, in accordance with some embodiments;

FIG. 4 is a cross-sectional profile view illustrating formation of a HSQDL workpiece, in accordance with some embodiments;

FIGS. 5, 6, and 7 illustrate a cross-sectional profile view of a HSQDL, in accordance with some embodiments;

FIG. 8 illustrates a plan view of a HSQDL, in accordance with some embodiments;

FIG. 9 illustrates a cross-sectional profile view of a HSQDL, in accordance with some further embodiments;

FIG. 10 illustrates a mobile computing platform and a data server machine comprising a silicon PIC including a plurality of HSQDLs, in accordance with some embodiments; and

FIG. 11 is a functional block diagram of an electronic computing device, that may implement one or more of the components of the mobile platform or data serve machine illustrated in FIG. 10, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

The inventors have found that reducing device contact area and/or a width of a III-V material feature (e.g., a III-V mesa) to improve photon and electron confinement of an HSQDL in the hope of improving laser injection efficiency and reducing threshold laser current can detrimentally increase thermal impedance of the HSQDL. The inventors have further found that higher thermal impedance can lead to significant laser self-heating and thermal rollover effects where laser output declines sharply as laser current increases. In accordance with embodiments herein, the inventors have solved this tradeoff by controlling the electrical resistivity of III-V material to achieve low threshold currents without early thermal rollover. The HSQDL architectures and techniques further described below can therefore achieve the electrical resistance and current confinement characteristics of a narrow-width QD laser concurrently with the lower thermal resistance of a wider-width QD laser.

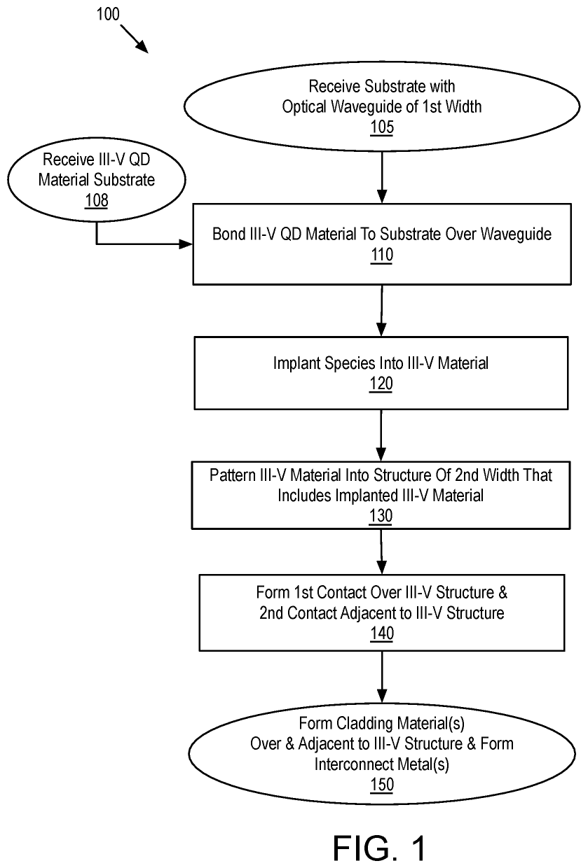

FIG. 1 is a flow diagram of methods 100 for fabricating a HSQDL, in accordance with some embodiments. Methods 100 may be practiced to fabricate a hybrid silicon quantum dot laser having one or more of the structural attributes described herein. Methods 100 may also be practiced to fabricate other hybrid silicon quantum dot laser structures, or any other QD laser architectures that face similar self-heating challenges. In some exemplary embodiments, methods 100 integrate an HSQDL within one or more PICS, and more specifically with one or more silicon photonic chips. Although many examples are further described in the context of SiPh implementations, the exemplary HSQDL architectures may instead be implemented in alternative technologies (e.g., exclusively III-V) without departing from the principles disclosed herein.

Methods 100 begin at input 105 where a substrate is received. In exemplary hybrid-silicon embodiments, the substrate received includes silicon. The substrate received at input 105 includes at least one planar optical waveguide that has been fabricated upstream of methods 100 according to any technique(s) known in the art. The substrate may further comprise one or more other passive optical devices, such as (de) multiplexers, grating couplers. The substrate may also comprise active components such as modulators, SOAs and photodetectors. Such optical devices may have been fabricated into the substrate upstream of methods 100 according to any technique(s) known in the art. Such optical devices may also be fabricated into the substrate downstream of methods 100.

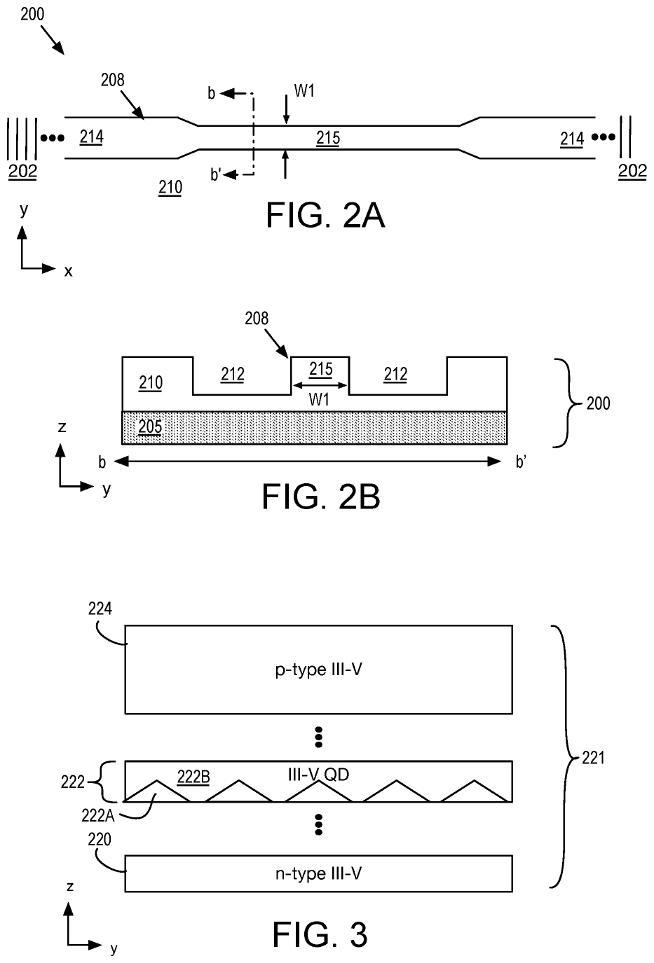

FIG. 2A is a plan view of a monolithic silicon PIC substrate 200, in accordance with some embodiments. FIG. 2B is a cross-sectional profile view of silicon PIC substrate 200 through the b-b′ plane demarked by dashed line in FIG. 2A, in accordance with some further embodiments. In some examples substrate 200 has a diameter of 300 mm, but may be of any dimension(s). Substrate 200 includes a planar optical waveguide 208 patterned within a substrate material layer 210 or within a thin film on substrate material layer 210. In exemplary embodiments where substrate material layer 210 comprises substantially monocrystalline silicon, waveguide 208 is also substantially monocrystalline silicon. In other embodiments where substrate material layer 210 comprises substantially monocrystalline silicon, waveguide 208 is predominantly silicon and nitrogen (e.g., Si₃N₄). As further illustrated in FIG. 2B, substrate material layer 210 is a top layer of a semiconductor-on-insulator (SOI) substrate material stack further comprising an insulator material layer 205. In exemplary embodiments, where substrate material layer 210 is substantially pure silicon, insulator material layer 205 is advantageously predominantly silicon and oxygen (e.g., SiO₂). One or more additional substrate material layers (not depicted) may be under, or on a back side of, insulator material layer 205. For example, insulator material layer 205 may be tween substrate material layer 210 and a backside substrate material layer, which may also be silicon.

Optical waveguide 208 may have any suitable architecture, such as, but not limited to, a substantially planar ridge waveguide of the type having the profile illustrated in FIG. 2B. In the illustrated example, optical waveguide 208 has a substantially constant transverse width W1 (e.g., in y-dimension) over a longitudinal length (e.g., in x-dimension) of an active waveguide region 215. At opposite ends of active waveguide region 215, waveguide 208 tapers out to passive waveguide regions 214 having a larger transverse width. Although the active waveguide width W1 may vary, in some exemplary silicon waveguide embodiments width W1 is in the range of 150 nm to 1 μm. A similar range is also applicable to the z-height (FIG. 2B) of at least active waveguide region 215. Air 212 is over a surface of PIC substrate 200 and adjacent to sidewalls of waveguide 208.

Although implementations may vary, at least a portion of optical waveguide 208 may comprise a mirror for establishing a resonant optical cavity within active waveguide region 215, for example according to any suitable Fabry-Perot (FP) laser architecture. In the illustrated embodiment, grating structures 202 are defined within passive waveguide regions 214 according to any suitable Distributed Bragg Reflector (DBR) laser architecture. In alternative Distributed Feedback (DFB) laser architectures, one or more grating structures 202 may be located within active waveguide region 215.

Returning to FIG. 1, methods 100 receive as a second input a donor substrate comprising a quantum dot material. The QD material stack and/or donor substrate advantageously has dimensions compatible with those of the PIC substrate (e.g., a diameter of 300 mm) and may comprise any suitable mechanical support material layer(s). The QD material stack is advantageously substantially monocrystalline. The QD material stack may have any number of material layers, one or more of which may have a chemical composition(s) and a micro/nano structure known to be suitable as a QD optical gain medium within one or more predetermined bands of the electromagnetic energy spectrum.

FIG. 3 illustrates a cross-sectional profile view of a material stack 221 having a P-i-N diode structure comprising at least one QD material layer 222, in accordance with some embodiments. As shown, QD material layer 222 is between an n-type material layer 220 and a p-type material layer 224. Material stack 221 is an epitaxial heterostructure that may have any number of additional QD material layers (represented by ellipses) between QD material layer 222 and each of material layers 220 and 224. Each QD material layer may have any thickness, with 10-50 nm being an exemplary thickness range.

In accordance with some embodiments, material layers 220, 222, 224 all comprise a Group III-V crystalline alloy material (i.e., a III-V material stack). In some examples, QD material layer 222 comprises quantum dots 222A of predominantly In and As, which may be binary InAs. QD material layer 222 may further comprise a shell material 222B of another III-V alloy having a distinct chemical composition with a suitable optical band offset and/or lattice mismatch with that of quantum dots 222A. In some embodiments where quantum dots 222A are predominantly In and As, shell material 222B has more Ga than quantum dots 222A (e.g., shell material 222B is InGaAs while quantum dots 222A are binary InAs). Although such embodiments are suitable for optical gain within a particular energy band (e.g., IR band of 850 nm-940 nm), the chemical composition and/or nanostructure of QD material layer 222 may be varied over a range of binary, ternary or quaternary III-V alloys. For example, QD material layer 222 may instead comprise InGaAsP, which is suitable for an IR band around 1550 nm.

N-type material layer 220 and p-type material layer 224 may comprise one or more impurity dopants, which may vary with the majority constituents of material layers 220, 224. For example, in some embodiments where material layers 220 and 224 are both binary or ternary alloys including Ga and As, n-type material layer 220 may comprise carbon, beryllium, magnesium, zinc, or cadmium while p-type material layer 224 may comprise silicon, tellurium or carbon. Electrically active impurity concentrations may vary with implementation to achieve any bulk electrical resistivity suitable for the application. Thicknesses of material layers 220, 224 may also vary with implementation. In some exemplary embodiments, n-type material layer has a thickness of 5-500 nm while p-type material layer 224 has a thickness of 1-2 μm.

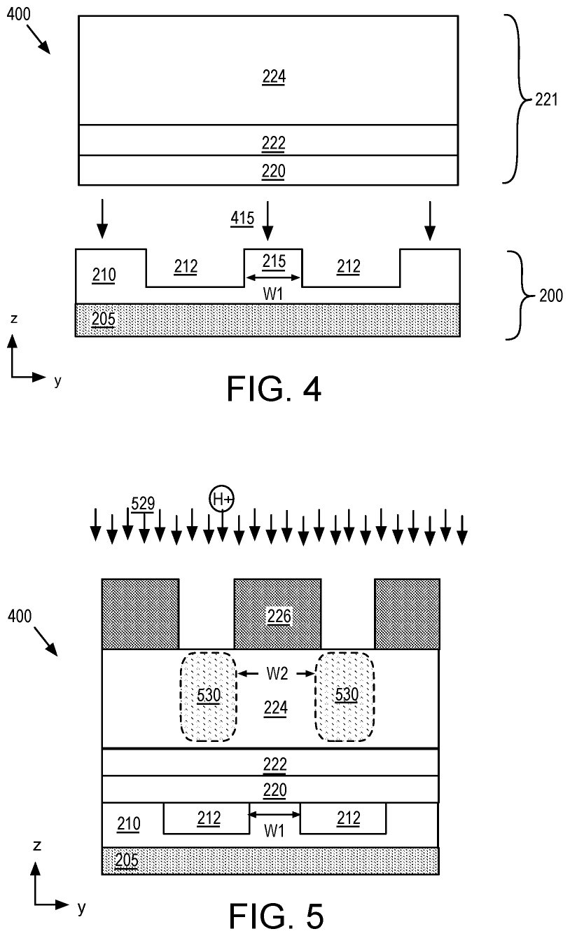

Returning to FIG. 1, methods 100 continue at block 110 where a material stack including one or more QD material layers is transferred from the donor substrate received at input 108 to the PIC substrate received at input 105. Any substrate (wafer)-level film bonding process may be practiced at block 110 to form a hybrid material structure. The term “hybrid” is in reference to resulting structure including non-silicon (e.g., III-V) material layers bonded to underlying silicon (or a thin film material layer thereon). Once bonded, the donor substrate may be removed to complete transfer of the QD material layers. FIG. 4 is a cross-sectional profile view illustrating formation of a HSQDL workpiece 400, in accordance with some embodiments where material stack 221 is bonded over PIC substrate 200. As shown, bonding process 415 places n-type material layer 220 proximal to optical waveguide 208 and p-type material layer 224 distal from waveguide 208. In the illustrated example, n-type material layer 220 is in direct contact with waveguide active region 215. Material stack 221 bridges over air 212 and extends over an adjacent portion of substrate material layer 210.

Following the formation of a hybrid silicon-III/V structure, HSQDL fabrication continues with patterning of at least some of the III-V material layers into a structural feature, and with electrical isolation that entails modulating an electrical resistance of at least some portion of the structural QD laser feature. A dimensionally larger QD laser feature achieves advantageously high laser thermal conductivity because III-V material layers have high thermal conductivity. Advantageously high photon and electron confinement may be achieved within a dimensionally larger QD laser features by increasing the electrical resistance of at least some portion of the QD laser features. Depending on implementation, III-V material may be first patterned into QD laser features and then electrically isolated or III-V material may be first electrically isolated and then patterned into QD laser features.

In exemplary embodiments, electrical resistivity of a portion of one or more layers of a III-V material stack is modulated to a define an electrical current channel that is significantly smaller in width than the width of a patterned structure comprising that layer. In some embodiments where a III-V material layer is in-situ doped to have low electrical resistivity during an epitaxial growth process, modulation of a portion of that material layer entails significantly increasing the electrical resistivity of a portion outside of the current channel width. Hence, for exemplary embodiments illustrated in FIG. 4 where p-type material layer 224 is distal from waveguide 208, modulation of the electrical resistivity of a portion of p-type material layer 224 entails increasing the material's electrical resistivity to a retain only a small channel width of p-type material having low electrical resistivity. For alternative embodiments where the material stack 221 is inverted from that illustrated in FIG. 4, a similar technique can be practiced on n-type material layer 220.

Modulating the electrical resistivity within a layer in a III-V material stack can also entail decreasing the electrical resistivity of a channel region. For example, if a III-V material is not in-situ doped and is instead epitaxially grown with intrinsic impurity levels to have a higher electrical resistivity, modulation of a portion of that material may instead entail reducing the electrical resistivity of a similarly narrow current channel portion through impurity doping and thermal activation.

In the example illustrated in FIG. 1, methods 100 continue at block 120 where a species is implanted into one or more layers of III-V material. For implant isolation embodiments, III-V material laterally offset from the underlying optical waveguide is subjected to implant. The implantation increases electrical resistivity (i.e., reduces electrical conductivity) of a portion of the III-V material laterally adjacent to the underlying optical waveguide so that an electrical current channel of low electrical resistivity is confined to a portion of the material directly above the optical waveguide. Resistivity of an impurity-doped crystalline semiconductor material may be increased through energy deposited damage of the crystalline lattice structure, which is thought to introduce deep level charge carrier traps. The implantation process performed at block 120 may therefore comprise implanting any species, at any dose and energy suitable for increasing the resistivity of a defined portion of an uppermost impurity-doped material layer that is otherwise of lower electrical resistivity.

In the example illustrated in FIG. 5, HSQDL workpiece 400 is exposed to an ion implantation process 529. In some advantageous embodiments, implantation process 529 comprises implanting protons through openings in an implant mask 226 and into p-type material layer 224. Protons are advantageous for their large penetration depth. In alternative embodiments, other species, such as He, for example, may be implanted into p-type material layer 224. Implantation process 529 forms two electrically resistive regions 530 laterally adjacent to an intervening current channel of low electrical resistivity within a transverse channel width W2. Electrically resistive regions 530 have an electrical resistivity (e.g., sheet resistivity) that is advantageously at least 2 orders of magnitude higher than the electrical resistivity within channel width W2 and may be 5 orders of magnitude higher, or higher.

Electrical resistivity of resistive regions 530 may be correlated to an electrical test structure having substantially the same III-V alloy composition, impurity doping and exposure to implant as regions 530. However, an electrical resistivity contrast can also be directly visualized with a scanning electron microscope (SEM) analysis of an HSQDL structure. For example, the structures substantially as illustrated in FIG. 5 may be imaged with a SEM and, because of their greater resistivity, resistive regions 530 will appear significantly darker than the portion of p-type material layer 224 that is within channel width W2.

In exemplary embodiments, channel width W2 at least equal to transverse waveguide width W1 and may be 1-3 times width W1. In embodiments where width W1 is less than 1 μm, channel width W2 may be in the range of 2-6 μm, for example. Ideally, channel width W2 is centered over width W1. Electrically resistive regions 530 advantageously extend to a depth of at least one-half the thickness of p-type material layer 224. As shown in FIG. 5, electrically resistive regions 530 may be contained within p-type material layer 224. In the illustrated example, electrically resistive regions 530 do not intersect QD material layer 220, avoiding damage within the underlying optical gain medium of QD material layer 220.

Returning to FIG. 1, methods 100 continue at block 130 where one or more III-V material layers are subtractively patterned (i.e., etched) into a mesa or ridge structure that includes the III-V material that was exposed to the species implant at block 120. Although now comprising some material of high electrical resistivity, all the III-V material retains advantageously low thermal resistivity (i.e., high thermal conductivity), which will improve thermal transport from the optical gain material and reduce the onset of thermal rollover during operation of an HSQDL. In FIG. 1, the patterning process performed at block 130 is illustrated as following the implantation block 120. However, in alternative embodiments the sequence of blocks 120 and 130 may be reversed.

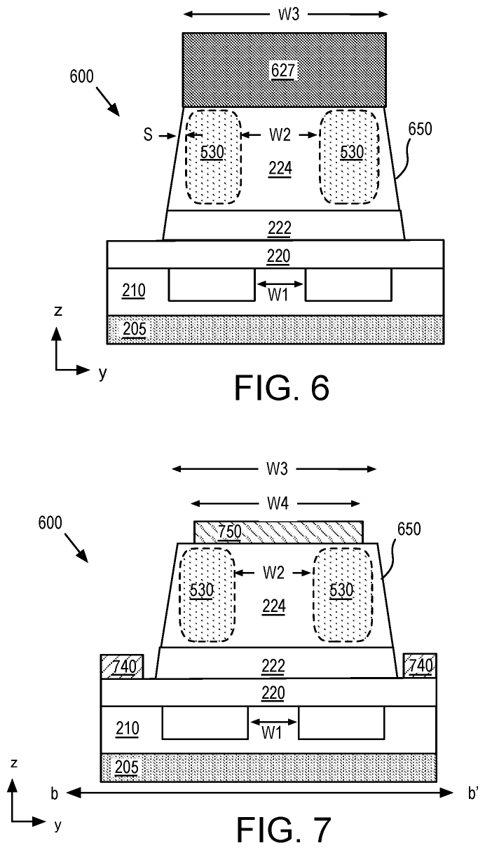

In the example illustrated in FIG. 6, one or more etch processes have defined an HSQDL structure 600 that includes a QD material mesa structure with a sidewall 650 etched according to a patterned etch mask 627. As shown, at least p-type material layer 224 and QD material layer 220 of a blanket III-V material stack have been etched into a mesa structure having a minimum transverse mesa width W3. Mesa width W3 is significantly greater than current channel width W2. In the illustrated example, mesa width W3 is greater than channel width W2 by at least the width of resistive regions 530. Increasing mesa width W3 will reduce the thermal resistance of a HSQDL. For the illustrated example where mesa definition exposes n-type material layer 220, the lateral distance an n-contact may be located from the current channel can limit mesa width W3, for example to 20-50 μm. Advantageously, mesa width W3 is substantially centered with waveguide width W1. As further illustrated in FIG. 6, mesa sidewall 650 is laterally spaced apart from resistive regions 530 by an intervening portion of p-type material having lower electrical resistivity. This sidewall space S may be, for example 1-2 μm, and may reduce charge carrier surface recombination, and/or have other performance advantages.

Returning to FIG. 1, methods 100 continue at block 140 where device contact metallization is formed on the HSQDL structure. For an exemplary III-V material mesa, a first contact (e.g., p-contact) metallization feature may be formed over a top surface of the mesa while a second contact (e.g., n-contact) metallization feature may be formed adjacent to the III-V material mesa. In the example illustrated in FIG. 7, a contact metallization feature 740 is in direct contact with n-type material layer 220 adjacent to opposing mesa sidewalls 650. Contact metallization feature 740 may have any chemical composition known to be suitable for an ohmic or tunneling electrical contact to n-type material layer 220. Another contact metallization feature 750 is in direct contact with p-type material layer 224. Contact metallization feature 750 may have any chemical composition known to be suitable for an ohmic or tunneling electrical contact to p-type material layer 224. Contact metallization feature 750 may be in direct contact with electrically resistive regions 530, or resistive regions 530 may be spaced apart (i.e., deeper than) the interface between contact metallization feature 750 and p-type material layer 224. In exemplary embodiments, contact metallization feature 750 has a contact width W4 that is significantly greater than current channel width W2. For example, contact width W4 may be 80%, or more, of mesa width W3. The larger width W4 may improve top side heat extraction over the larger mesa width W.

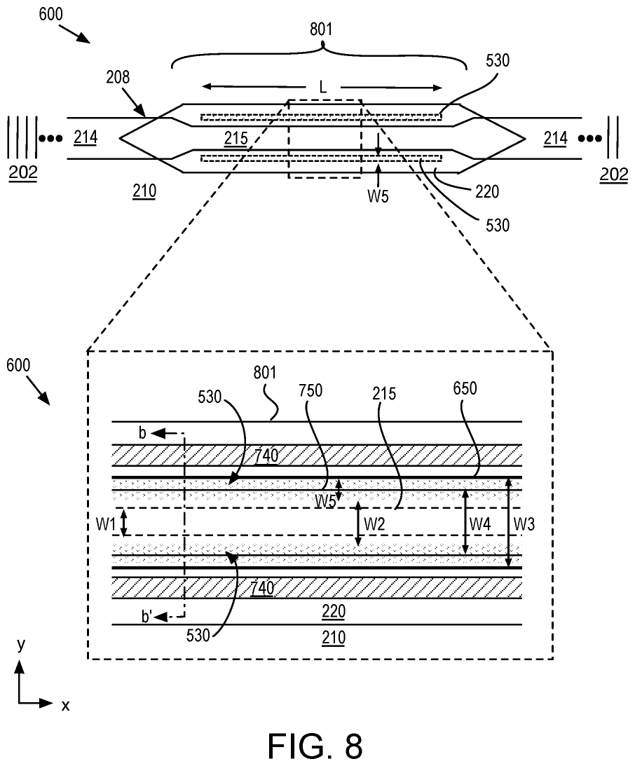

FIG. 8 further illustrates a plan view of HSQDL structure 600. As shown, QD mesa structure 801 has a substantially constant width over a length L. Length L may vary with implementation, for example from 100 μm to 1 mm, or more. Resistive regions 530 comprise two stripes within QD mesa structure 801. Each stripe has a substantially constant isolation width W5 extending over substantially all of length L, for example terminating near the tapers of optical waveguide 208. Isolation width W5 may vary with implementation (e.g., 1-10 μm, or more). Over length L, QD mesa structure 801 may be substantially as further illustrated within the expanded view. A layout of the HSQDL features described above is shown in the expanded view with the widths W1, W2, W3, W4 and W all being substantially constant over length L.

Returning to FIG. 1, HSQDL fabrication methods 100 end at output 150 where one or more cladding materials may be formed over the laser diode structure. To further reduce the thermal resistance of the laser diode structure, thick metal can be placed over the laser. In some examples, the thick metal is electrically coupled to a contact metallization feature as both an electrical power supply rail and a topside laser heat dissipator. Combined with a wide QD mesa, for example enabled by proton implantation, and the inherent temperature resilient properties of quantum dots, HSQDL structures fabricated in accordance with methods 100 can achieve excellent high-temperature performance.

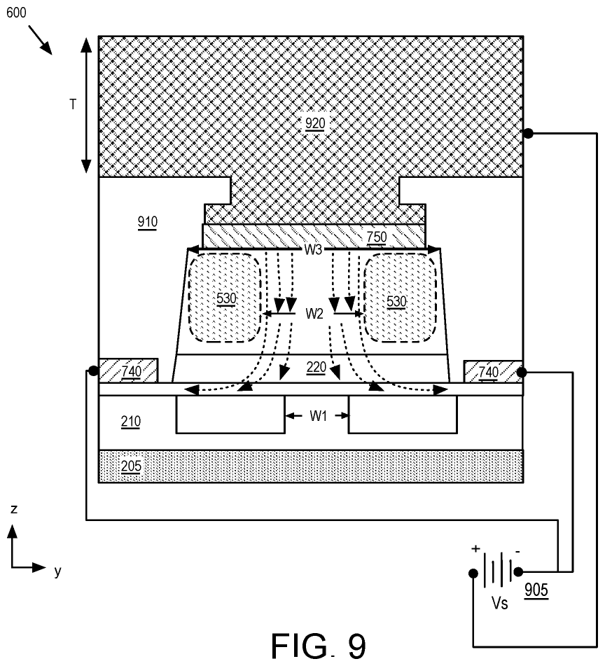

FIG. 9 illustrates a cross-sectional view of HSQDL structure 600 along a y-z plane defined by the b-b′ line illustrated in FIG. 8 following the formation of one or more cladding materials 910 and formation of interconnect metal 920. Cladding materials 910 may comprise any dielectric material having suitable electrical and optical (e.g., refractive index) properties. Interconnect metal 920 is in direct contact with p-contact metallization 750. One rail of power supply 905 is coupled to contact metallization feature 750 through interconnect metal 920. Another rail of power supply 905 is coupled to contact metallization features 740. When powered, resistive regions 530 confine a channel current (represented by dotted arrows) to channel width W2.

Interconnect metal 920 may comprise one or more metals, such as, but not limited to, Al or Cu. Notably, interconnect metal 920 has a thickness T exceeds electrical power delivery demands of HSQDL 600. For example, thickness T may be 8-10 μm, or more, to enhance topside dissipation of heat extracted through mesa width W3. Interconnect metal 920 may be further coupled to a package level thermal solution (not depicted), such as an external heat spreader and/or heat exchanger, etc.

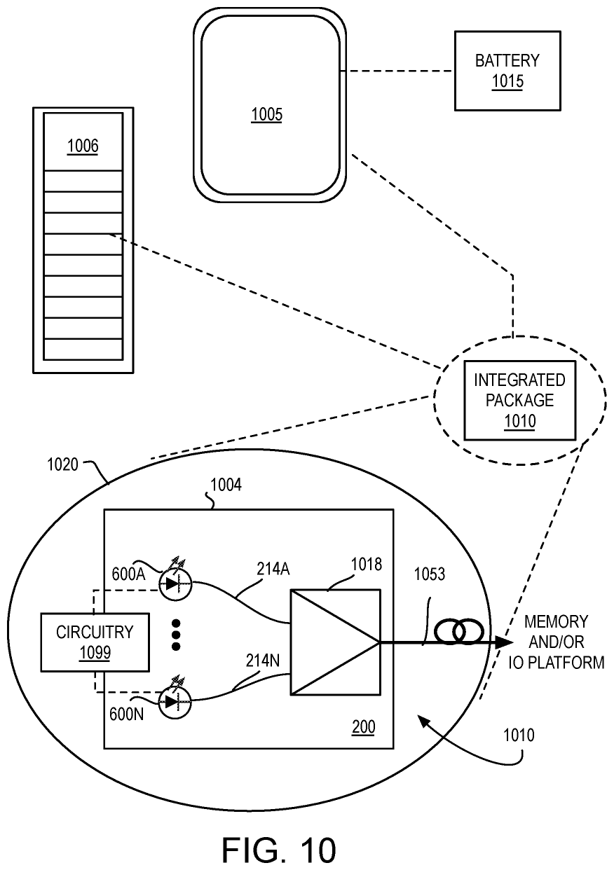

The HSQDL structures and systems described herein may be implemented in a wide variety of applications and platforms. FIG. 10 illustrates a mobile computing platform 1005 and data server platform 1006, each employing an optical link with one or more HSQDL structure, for example as described elsewhere herein. Platform 1006 may be any commercial server, for example including any number of high-performance computing platforms disposed within a rack and networked together for electronic data processing. The mobile platform 1005 may be any portable device configured for each of electronic data display, electronic data processing, wireless electronic data transmission, or the like. For example, the platform 1005 may be any of a tablet, a smart phone, laptop computer, etc., and may include an integrated or disintegrated package 1010, and a battery power supply 1015.

Platforms 1005 or 1006 may each include a PIC 1004, illustrated in expanded view 1020. PIC 1004 may be one of a plurality of PICs in package 1010, or a stand-alone packaged PIC. PIC 1004 includes a waveguide-coupled HSQDL, in accordance with some embodiments. A plurality of wavelengths output by a plurality of HSQDL structures 600A-600N to a plurality of optical waveguides 214A-214N disposed on substrate 200 may be combined with an optical multiplexer 1018 into wave division multiplexed (e.g., DWDM) optical beam. The optical beam may be coupled off-chip to an optical wire or fiber 1053, for example through top-side coupling or edge coupling. HSQDL structures 600A-600N are electrically coupled to downstream integrated comb driver circuitry 1099, which may for example further include a voltage supply. HSQDL structures 600A-600N may output at different center wavelengths (e.g., with 0.5-1.0 nm spacing). In certain embodiments, comb driver circuitry 1099 is implemented with CMOS transistors also disposed on the substrate 200. In other embodiments, comb driver circuitry 1099 is implemented with CMOS transistors external of PIC 1004.

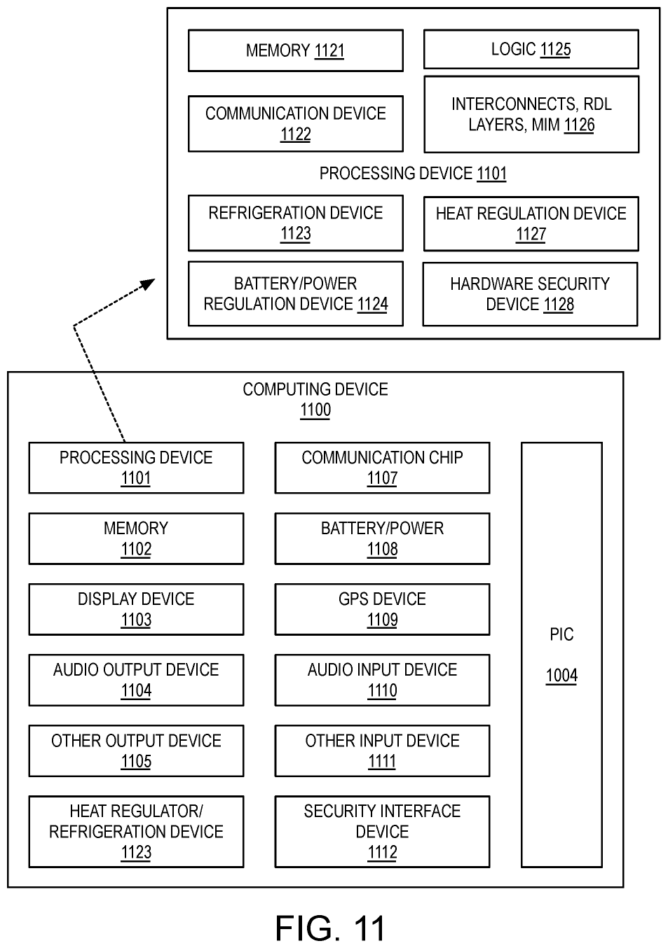

FIG. 11 is a block diagram of a cryogenically cooled computing device 1100 in accordance with some embodiments. For example, one or more components of computing device 1100 may include any of the HSQDL structures discussed elsewhere herein. A number of components are illustrated in FIG. 11 as included in computing device 1100, but any one or more of these components may be omitted or duplicated, as suitable for the application. In some embodiments, some of the components included in computing device 1100 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled.

Computing device 1100 may include a processing device 1101 (e.g., one or more processing devices). As used herein, the term processing device or processor indicates a device that processes electronic data from registers and/or memory to transform that electronic data into other electronic data that may be stored in registers and/or memory. Processing device 1101 may include a memory 1121, a communication device 1122, a refrigeration/active cooling device 1123, a battery/power regulation device 1124, logic 1125, interconnects 1126, a heat regulation device 1127, and a hardware security device 1128.

Processing device 1101 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1101 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing 1101 shares a package with memory 1102. This memory may be used as cache memory and may include embedded dynamic random-access memory (eDRAM) or spin transfer torque magnetic random-access memory (STT-M RAM).

Computing device 1100 may include a heat regulation/refrigeration device 1123. Heat regulation/refrigeration device 1123 may maintain processing device 1101 (and/or other components of computing device 1100) at a predetermined low temperature during operation. This predetermined low temperature may be any temperature discussed elsewhere herein.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an optical data link comprising a HSQDL, for example as described elsewhere herein.

In some embodiments, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some embodiments, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a global positioning system (GPS) device 1109 (or corresponding interface circuitry, as discussed above). GPS device 1109 may be in communication with a satellite-based system and may receive a location of computing device 1100, as known in the art.

Computing device 1100 may include another output device 1105 (or corresponding interface circuitry, as discussed above). Examples include an audio codec, a video codec, a printer, a wired or wireless transmitter for providing information to other devices, or an additional storage device.

Computing device 1100 may include another input device 1111 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, managing access lists, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that practice of the disclosed techniques and architectures is not limited to the embodiments so described but can be modified and altered without departing from the scope of the appended claims. For example, the above embodiments may include specific combinations of features as further provided below.

In first examples, an apparatus comprises a planar optical waveguide comprising silicon; and a mesa comprising a quantum dot (QD) material over the planar optical waveguide, wherein the mesa has a first width, and wherein electrical resistivity within at least one material layer of the mesa varies over the first width.

In second examples, for any of the first examples the electrical resistivity of the at least one material layer is lower over a second width spanning a central portion of the mesa, and higher proximal to a sidewall of the mesa.

In third examples, for any of the second examples the optical waveguide has a third width, smaller than the second width.

In fourth examples, for any of the second through third examples the at least one material layer comprises a p-type material layer, and the electrical resistivity over the second width within the p-type material layer is at least two orders of magnitude lower than the electrical resistivity within the p-type material layer beyond the second width.

In fifth examples, for any of the second through fourth examples the optical waveguide is crystalline silicon and has a width less than 1 μm, the first width is at least 10 μm and the second width is less than 6 μm.

In sixth examples, for any of the fifth examples the first width is at least 20 μm.

In seventh examples, for any of the fifth through sixth examples the p-type material layer is a crystalline III-V material layer of a first thickness, and the p-type material layer comprises two electrically resistive regions adjacent to opposite sides of the central portion, the two resistive regions each comprising at least half the first thickness.

In eighth examples, for any of the seventh examples the two resistive regions each have a width of at least 1 μm.

In ninth examples, for any of the seventh through eighth examples the further comprising a contact metallization feature over the mesa, the contact metallization spanning the second width and over at least a majority of two the resistive regions.

In tenth examples, for any of the second through ninth examples the apparatus further comprises a contact metallization feature over the mesa, the contact metallization feature having a width between the first width and the second width. The apparatus further comprises an interconnect metallization feature over, and in direct contact with, the contact metallization feature, wherein the interconnect metallization feature has a different chemical composition than the contact metallization feature and has a thickness of at least 8 μm.

In eleventh examples, photonic integrated circuit (PIC) comprises a plurality of optical waveguides extending over a crystalline silicon substrate, and a plurality of hybrid silicon-quantum dot lasers (HSQDLs). Each of the HSQDLs comprises a stack of III-V semiconductor material over an active portion of a corresponding one of the optical waveguides. The stack comprises a QD material layer between a p-type material layer and an n-type material layer, the stack has a first width, larger than a width of the active portion of the optical waveguide, and electrical resistivity of one of the p-type material layer or n-type material layer varies over the first width.

In twelfth examples, for any of the eleventh examples the electrical resistivity is lower over a second width spanning a central portion of the stack, and higher within an edge portion proximal to a sidewall of the stack.

In thirteenth examples, for any of the eleventh through twelfth examples each of the optical waveguides is crystalline silicon and has a width less than 1 μm, the first width is at least 10 μm, and the second width is less than 5 μm.

In fourteenth examples, for any of the eleventh through thirteenth examples each of the HSQDLs is to output at a different center wavelength.

In fifteenth examples, a method comprises forming a hybrid structure comprising a III-V material stack over an optical waveguide comprising predominantly silicon, wherein the III-V material stack comprises a quantum dot (QD) material layer over a first impurity doped material layer and under a second impurity doped material layer. The method comprises increasing electrical resistivity of the second impurity doped material layer outside a first region of the III-V material stack directly over the waveguide, or lowering electrical resistivity of the second impurity doped material layer within the first region of the III-V material stack. The method comprises forming a first contact to the first impurity doped material layer, and forming a second contact to the second impurity doped material layer.

In sixteenth examples, for any of the fifteenth examples increasing the electrical resistivity of the second impurity doped material layer comprises implanting one or more species into the second impurity doped material layer.

In seventeenth examples, for any of the sixteenth examples implanting the one or more species induces crystal lattice damage.

In eighteenth examples, for any of the sixteenth through seventeenth examples the one or more species comprises a proton or a helium ion.

In nineteenth examples, for any of the sixteenth through eighteenth examples the method further comprises applying an implant mask over the first region prior to implanting the one or more species.

In twentieth examples, for any of the fifteenth through nineteenth examples, the method further comprises forming a mesa by etching at least partially through both the second impurity doped material layer and the QD material layer. The mesa comprises sidewalls located beyond the first region.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosed techniques and architectures should therefore be determined with reference to the appended claims, along with the full scope of equivalents to which such claims are entitled.

What is claimed is:

1. A laser source, comprising:
a planar optical waveguide comprising silicon; and
a mesa comprising a quantum dot (QD) material over the planar optical waveguide, wherein the mesa has a first width, and wherein electrical resistivity within at least one material layer of the mesa varies over the first width.

2. The laser source of claim 1, wherein the electrical resistivity of the at least one material layer is lower over a second width spanning a central portion of the mesa, and higher proximal to a sidewall of the mesa.

3. The laser source of claim 2, wherein the optical waveguide has a third width, smaller than the second width.

4. The laser source of claim 2, wherein:
the optical waveguide is crystalline silicon and has a width less than 1 μm;
the first width is at least 10 μm; and
the second width is less than 6 μm.

5. The laser source of claim 2, wherein the at least one material layer comprises a p-type material layer, and wherein the electrical resistivity over the second width within the p-type material layer is at least two orders of magnitude lower than the electrical resistivity within the p-type material layer beyond the second width.

6. The laser source of claim 5, wherein the first width is at least 20 μm.

7. The laser source of claim 5, wherein:
the p-type material layer is a crystalline III-V material layer of a first thickness; and
the p-type material layer comprises two electrically resistive regions adjacent to opposite sides of the central portion, the two resistive regions each comprising at least half the first thickness.

8. The laser source of claim 7, wherein the two resistive regions each have a width of at least 1 μm.

9. The laser source of claim 7, further comprising a contact metallization feature over the mesa, the contact metallization spanning the second width and over at least a majority of two the resistive regions.

10. The laser source of claim 2, further comprising:
a contact metallization feature over the mesa, the contact metallization feature having a width between the first width and the second width; and
an interconnect metallization feature over, and in direct contact with, the contact metallization feature, wherein the interconnect metallization feature has a different chemical composition than the contact metallization feature and has a thickness of at least 8 μm.

11. A photonic integrated circuit (PIC), comprising:
a plurality of optical waveguides extending over a crystalline silicon substrate; and
a plurality of hybrid silicon-quantum dot lasers (HSQDLs), wherein each of the HSQDLs comprises:
a stack of III-V semiconductor material over an active portion of a corresponding one of the optical waveguides, wherein:
the stack comprises a QD material layer between a p-type material layer and an n-type material layer;
the stack has a first width, larger than a width of the active portion of the optical waveguide; and
electrical resistivity of one of the p-type material layer or n-type material layer varies over the first width.

12. The PIC of claim 11, wherein the electrical resistivity is lower over a second width spanning a central portion of the stack, and higher within an edge portion proximal to a sidewall of the stack.

13. The PIC of claim 12, wherein:
each of the optical waveguides is crystalline silicon and has a width less than 1 μm;
the first width is at least 10 μm; and
the second width is less than 5 μm.

14. The PIC of claim 11, wherein each of the HSQDLs is to output at a different center wavelength.

15. A method comprising:
forming a hybrid structure comprising a III-V material stack over an optical waveguide comprising predominantly silicon, wherein the III-V material stack comprises a quantum dot (QD) material layer over a first impurity doped material layer and under a second impurity doped material layer;
increasing electrical resistivity of the second impurity doped material layer outside a first region of the III-V material stack directly over the waveguide, or lowering electrical resistivity of the second impurity doped material layer within the first region of the III-V material stack;
forming a first contact to the first impurity doped material layer; and
forming a second contact to the second impurity doped material layer.

16. The method of claim 15, wherein increasing the electrical resistivity of the second impurity doped material layer comprises implanting one or more species into the second impurity doped material layer.

17. The method of claim 16, wherein implanting the one or more species induces crystal lattice damage.

18. The method of claim 17, wherein the one or more species comprises a proton or a helium ion.

19. The method of claim 17, further comprises applying an implant mask over the first region prior to implanting the one or more species.

20. The method of claim 15, further comprising forming a mesa by etching at least partially through both the second impurity doped material layer and the QD material layer, wherein the mesa comprises sidewalls located beyond the first region.
